(19) United States
(12) Patent Application Publication
(10) Pub. No.: US 2012/0134089 A1
(43) Pub. Date: May 31, 2012

(54) ELECTRONIC DEVICE

(75) Inventors: WEI WU, Shenzhen City (CN); XIN YANG, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/217,620

(22) Filed: Aug. 25, 2011

(30) Foreign Application Priority Data
Nov. 29, 2010 (CN) 201010563903.2

(51) Int. Cl. H05K 7/00

(52) U.S. Cl. 361/679.4

(57) ABSTRACT

An electronic device includes a main body, an input device, and a locking mechanism. The main body defines a receiving portion partially surrounded by a bottom portion. The input device is capable of being secured to the receiving portion to function as a touchpad and being detachable from the receiving portion to function as a wireless mouse, and the input device being supported by the bottom portion when secured in the receiving portion. The locking mechanism is disposed in the receiving portion for securing the input device to the receiving portion in a first direction substantially perpendicular to the bottom portion.

### BACKGROUND

1. Technical Field

The present disclosure relates to electronic devices, and more particular to an electronic device with a touchpad.

2. Description of Related Art

Portable electronic devices, such as notebook computers or personal digital assistances, often include a housing and an input device for controlling the coordinates of a cursor on the screen of the portable electronic device. The input device is secured to the housing to function as a touchpad. However, most input devices are permanently secured to the housing and this restricts the functionality of the input device.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a perspective view of an electronic device according to an embodiment of the present disclosure; the electronic device includes an input device.

FIG. 2 is a partially disassembled view of the electronic device of FIG. 1.

FIG. 3 is a cross-sectional view taken along line III-III of FIG. 1.

FIG. 4 is an enlarged sectional view of part IV in FIG. 1.

FIG. 5 is a cross-sectional view of taken along line V-V FIG. 1.

FIG. 6 is an explanatory view showing the input device after being removed from the electronic device in FIG. 1.

FIG. 7 is an enlarged sectional view of part VIII of FIG. 6.

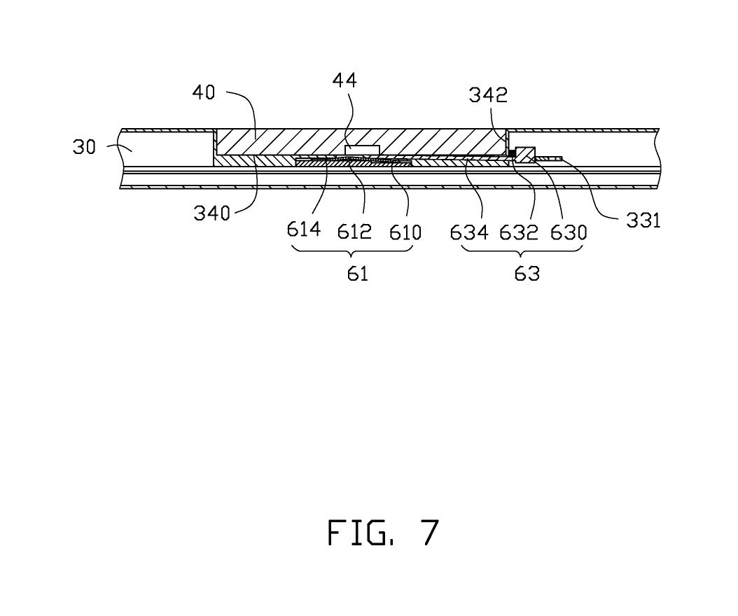

FIG. 8 is a cross-sectional view taken along line VII-VII of FIG. 6.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

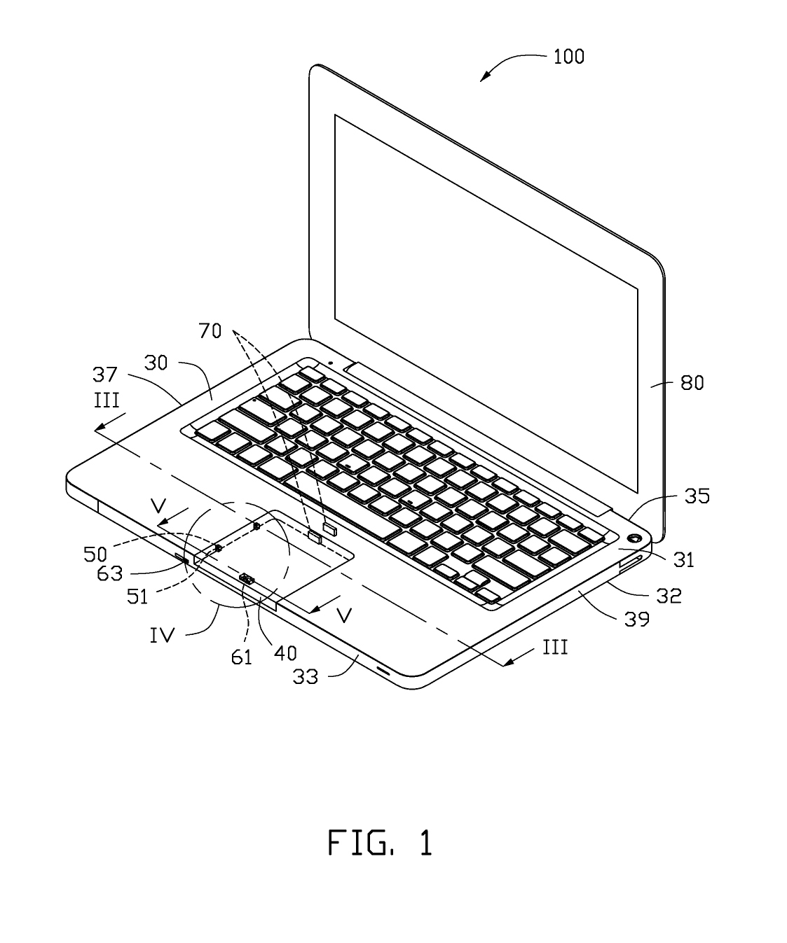

Referring to FIG. 1, an electronic device 100 includes a main body 30, an input device 40 detachably secured to the main body 30, and a display 80 pivotably connected to the main body 30. In some embodiments, the electronic device 100 may be a notebook computer. The input device 40 is used for controlling the coordinates of a cursor on the display 80, and is capable of being secured to the main body 30 to function as a touchpad and being detachable from the main body 30 to function as a wireless mouse.

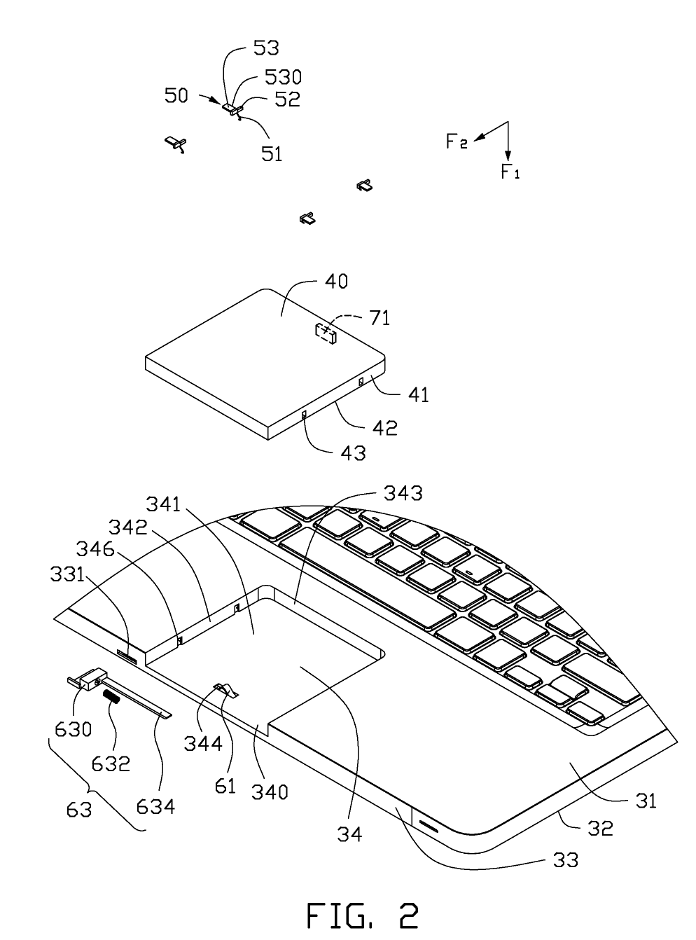

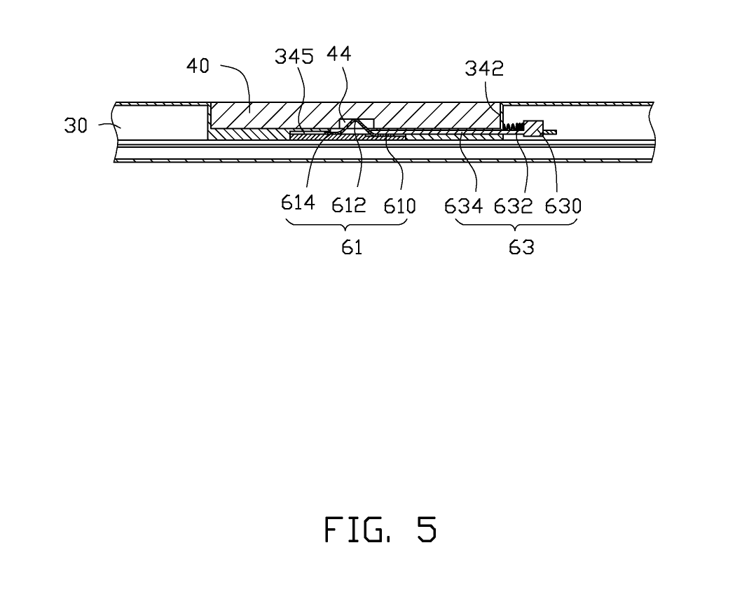

The main body 30 includes a top case 31, a bottom case 32 opposite to the top case 31, and four side walls 33, 35, 37, 39 protruding from the bottom case 32. The top case 31, the bottom case 32, and the four side walls 33, 35, 37, 39 cooperatively define an accommodating space (not labeled). As shown in FIG. 2, the top case 31 defines a recess to form a receiving portion 34 for receiving the input device 40. An opening 340 at the side wall 33 communicates with the receiving portion 34. Partially surrounding the receiving portion 34 is a bottom portion 341, two opposite first side portions 342 and a second side portion 343 connected to the first side portions 342. The second side portion 343 perpendicularly protrudes from the bottom portion 341 and faces the opening 340. The bottom portion 341 defines a first through hole 344 arranged adjacent to the opening 340. The bottom portion 341 further defines a sliding slot 345 (see FIG. 5) communicating with the first through hole 344. Each first side portion 342 defines a recess to define two first slots 346. The side wall 33 defines an elongated second through hole 331 extending longitudinally. The second through hole 331 is adjacent to the opening 340.

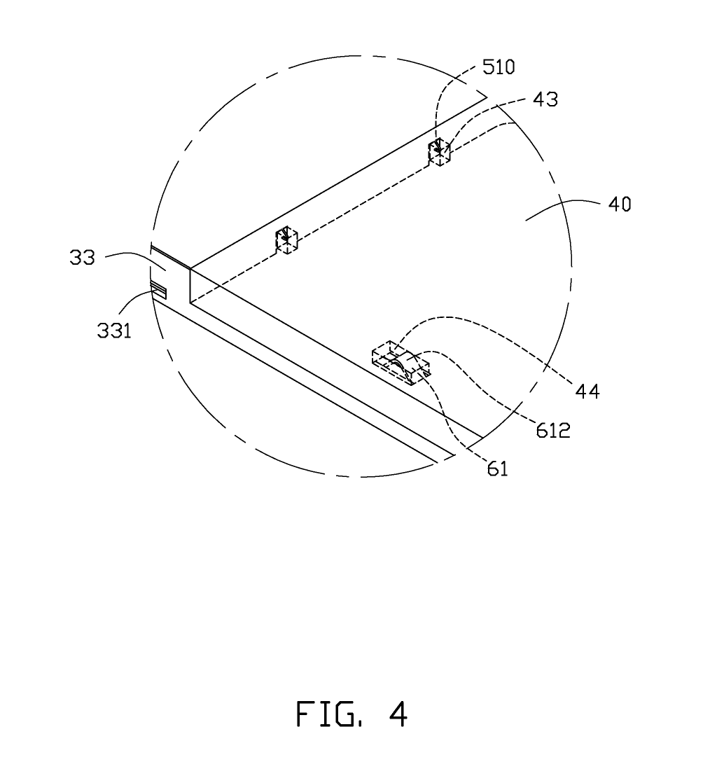

The input device 40 is substantially rectangular, and is received in the receiving portion 34. The input device 40 includes a bottom surface 42 corresponding to the bottom portion 341 and two opposite side ends 41 protruding from opposite rims of the bottom surface 42. The two side ends 41 respectively correspond to the two first side portions 342. Each side end 41 defines a recess defining two second slots 43 respectively corresponding to the first slots 346. The bottom surface 42 defines a recess defining a second slot 44 (see FIG. 4) corresponding to the first through hole 344.

Referring to FIGS. 1 and 2 again, the electronic device 100 further includes four locking mechanisms 50 for limiting the movement of the input device 40 in a first direction perpendicular to the bottom portion 341, and a restricting mechanism 61 for limiting the movement of the input device 40 in a second direction perpendicular to the side wall 33 and the first direction. The electronic device 100 further includes a push mechanism 63 and a repulsion mechanism 70. The push mechanism 63 is coupled to the restricting mechanism 61, and is operated to drive the restricting mechanism 61 to disengage from the input device 40, such that the input device 40 is allowed to move in the second direction. The repulsion mechanism 70 is used for driving the input device 40 to move in the second direction when the restricting mechanism 61 disengages from the input device 40.

The four locking mechanisms 50 are respectively disposed in the first slots 346 of the receiving portion 34. Each locking mechanism 50 includes a clasping member 51, a fixing member 52, and a repositioning member 53. The clasping member 51 is rotatably coupled to the fixing member 52, and is capable of being deformed in the first direction to be received in the corresponding first slot 346 to allow the input device 40 to be received in the receiving portion 34, and rebounding to its original state to extend out of the corresponding first side portion 342 and is inserted into the input device 40 to lock the input device 40. The clasping member 51 is also capable of rotating around an axis (not labeled) to be hidden in the corresponding first slot 346 or extend out of the corresponding first side portion 342. The fixing member 52 and the repositioning member 53 are received in the corresponding first slot 346. The repositioning member 53 is adapted to drive the clasping member 51 to rotate around the axis to extend out of the corresponding first side portion 342.

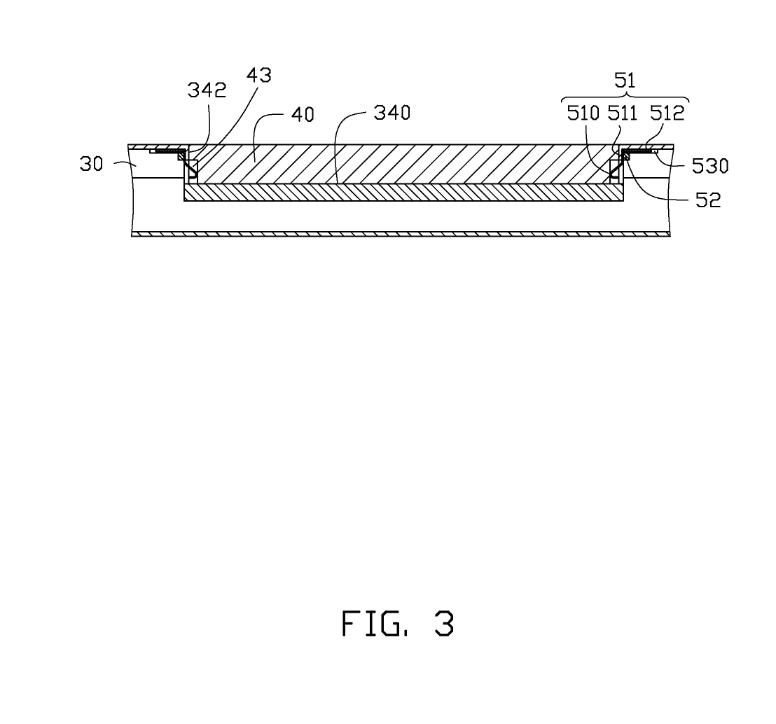

Referring to FIGS. 3 and 4, each clasping member 51 includes a connecting portion 511 rotatably coupled to the fixing member 52, a hook 510 and a driven portion 512 respectively disposed at two ends of the connecting portion 511. When a downward first force F1 presses each clasping member 51 (see FIG. 2) substantially parallel to the first direction, the hook 510 is deformed to be in an unlocked position and is received in the corresponding first slot 346 allowing the input device 40 to be received in the receiving portion 34. When the input device 40 is received in the receiving portion 34, the hook 510 rebounds to a locked position to extend out of the corresponding first side portion 342 and is inserted into the corresponding second slot 43 of the input device 40. The hook 510 is also capable of rotating around the connection portion 511 from a first position to be hidden in the corresponding first slot 346 when the clasping member 51 is pressed by a second force F2 (see FIG. 2) to a second position being rotated to extend out of the corresponding first side portion 342 by the repositioning member 53 when the second force F2 is released. Each hook 510 is substantially perpendicular to the corresponding first side portion 342 in the second position, and is substantially parallel to the corresponding first side portion 342 in the first position. The connecting portion 511 is substantially perpendicular to the bottom portion 341. The connecting portion 511 can be driven to rotate when the hook 510 rotates. The driving portion 512 is substantially perpendicular to the connecting portion 511 and the corresponding first side portion 342. The driving portion 512 is interchangeable between a detached position and an attached position when the hook 510 rotates between the first position and second position.

The four fixing members 52 are disposed in the first slots 346 respectively for securing the locking members 50 to the corresponding first side portion 342. Each fixing member 52 defines a through hole (not shown) for allowing the corresponding connecting portion 511 to pass through and rotate therein.

The repositioning members 53 are also received in the first slots 346 respectively. Each repositioning member 53 is made of magnetic material and attracts the corresponding driving portion 512 to return to the attached position from the detached position. Each repositioning member 53 includes a side section 530 substantially parallel to the driving portion 512. When the driving portion 512 is in the attached position, the side section 530 contacts the driving portion 512. When the driving portion 512 is in the detached position, the side section 530 keeps an angle with the driving portion 512.

Referring to FIGS. 2 and 5, the restricting mechanism 61 is received in the sliding slot 345 and includes a securing end 610, a free end 614 opposite to the securing end 610, and a body portion 612 defined between the securing end 610 and the free end 614. The securing end 610 is secured to one side of the sliding slot 345. The free end 614 is capable of sliding in the sliding slot 345. The body portion 612 is made of elastic material. In the illustrated embodiment, the restricting mechanism 61 is capable of interchanging between a first state with the body portion 612 being arch shaped for being inserted into the input device 40 and a second state with the body portion 612 being flat shaped for withdrawing from the input device 40.

The push mechanism 63 includes an operating member 630, a spring 632, and a resisting member 634. The operating member 630 is slidably received in the second through hole 331 with a portion extending out of the side wall 33. Opposite ends of the spring 632 are respectively secured to the operating member 630 and the internal surface of the first side portion 342. The spring 632 provides an elastic force for driving the operating member 630 to slide from a first end of the second through hole 331 adjacent to the receiving portion 34 to a second end opposite to the first end. The resisting member 634 is secured to the operating member 630 and is slidably received in the sliding slot 345. When the operating member 630 slides to an end of the second through hole 331 adjacent to the opening 340, the resisting member 634 is driven to slide along the sliding slot 345 to compress the body portion 612 into a flat shaped.

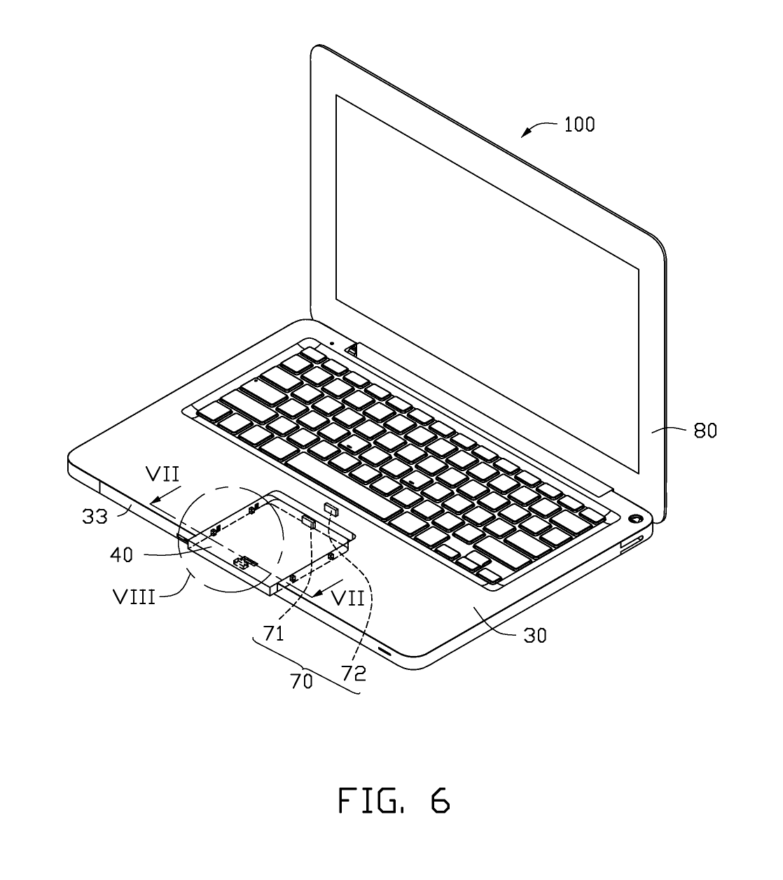

The repulsion mechanism 70 (FIG. 1) applies a repulsing force to drive the input device 40 to move in the second direction when the body portion 612 is in the second state. As shown in FIG. 6, the repulsion mechanism 70 in the illustrated embodiment includes a first magnet 71 and a second magnet 72 with magnetic polarity opposite to that of the first magnet 71. The first magnet 71 is disposed on the input device 40 and corresponds to the second side portion 343 of the receiving portion 34 when the second magnet 72 is disposed in the main body 30.

The assembly process will be described in detail in the following which only describes the assembly of one single component as an example since the components are disposed in the same way.

Before the input device 40 is received in the receiving portion 34, each hook 510 protrudes out of the corresponding first slot 346 to be in the second position. Each hook 510 at this time is substantially perpendicular to the corresponding first side portion 342. Meanwhile, the restricting mechanism 61 is in the first state and the body portion 612 extends through the first through hole 344 and is exposed out of the bottom portion 341.

To secure the input device 40 to the main body first the input device 40 is placed into the receiving portion 34 with the two side ends 41 thereof respectively contacting the two first side portions 342. Second, the input device 40 is pressed by a force F1 downward to deform the hook 510. The hook 510 is deformed to be received in the corresponding first slot 346 to allow the input device 40 to be received in the receiving portion 34, and rebounds to the locked position to lock the input device 40 to the receiving portion 34 in the first direction.

Meanwhile, the arch-shaped body portion 612 of the restricting mechanism 61 is inserted into the second slot 44 of the input device 40, to limit the movement of the input device 40 along the second direction perpendicular to the second side portion 343. At this time, although the repulsion mechanism 70 applies the repulsing force along the third direction to the input device 40, the repulsing force is not powerful enough to push the input device 40 to move in the second direction.

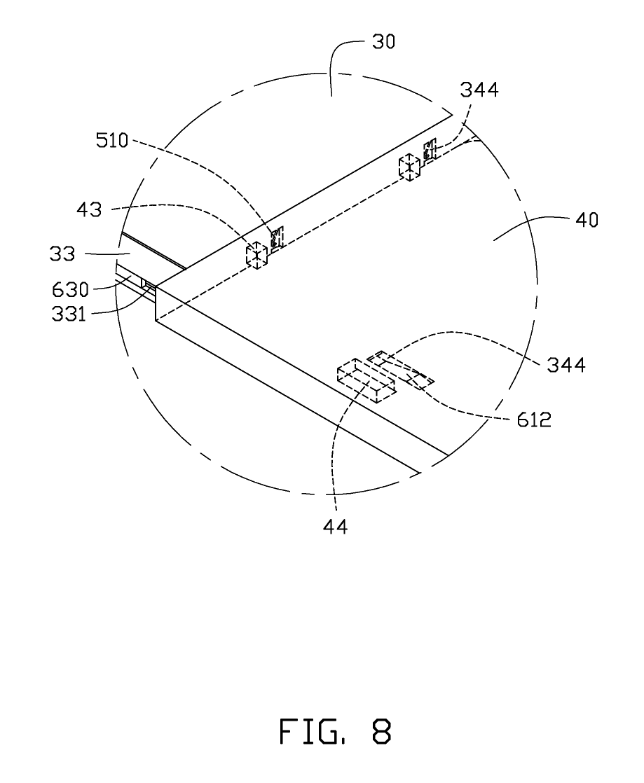

When the input device 40 is to be removed from the receiving portion 34, the operating member 630 is pushed to slide to an end of the second through hole 331 adjacent to the opening 340. During the process, the spring 632 is gradually compressed to store an elastic force, the actuating member 634 moves together with the operating member 630 to compress the body portion 612, and the body portion 612 is deformed to be flat shaped to disengage from the input device 40. Therefore, the restricting mechanism 61 is changed to the second state and no longer limits the movement of the input device 40 along the second direction. Meanwhile, the repulsing force from the repulsion mechanism 70 pushes the input device 40 to move along the second direction for a predetermined distance to be partly exposed outside the receiving portion 34, as shown in FIGS. 6 and 8.

Referring to FIG. 8, as the input device 40 moves in the second direction, the first side ends 41 of the input device 40 drives each hook 510 to rotate from the second position to the first position, and the driving portion 512 is driven to rotate to the detached position and forms an angle with the side section 530 of the corresponding repositioning member 53. At this time, each hook 510 no longer limits the movement of the input device 40 in the first direction, and the input device 40 is capable of being removed from the main body 30.

After the input device 40 is removed from the receiving portion 34, the spring 632 rebounds to drive the operating member 630 to slide back to its original position, the resisting member 634 moves together with the operating member 630 and no longer compresses the body portion 612 of the restricting mechanism 61. Therefore, the body portion 612 is arch shaped to be exposed in the receiving portion 34 by protruding out of the first through hole 344 again. Meanwhile, each driving portions 512 is attracted to return to the attached position under the magnetic force of the corresponding repositioning member 53 and contacts the side section 530 of the corresponding repositioning members 53, and the corresponding hook 510 is rotated to return to its second position.

It should be noted that although the input device 40 is restricted from moving along the second direction by the restricting mechanism 61, the hook 510 of each clasping member 51 can also restrict the input device 40 from moving along the second direction somewhat with the omission of the repulsion mechanism 70.

With the locking mechanisms 50 and the restricting mechanism 61, the input device 40 can be secured in the receiving portion 34 stably. With the push mechanism 63 and the repulsion mechanism 70, the input device 40 is easily detachable from the receiving portion 34.

Even though information and the advantages of the present embodiments have been set forth in the foregoing description, together with details of the mechanisms and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An electronic device, comprising:
a main body defining a receiving portion, the receiving portion comprises a bottom portion;
an input device capable of being secured to the receiving portion to function as a touchpad and being detachable from the receiving portion to function as a wireless mouse, and the input device being supported by the bottom portion when secured in the receiving portion; and
a locking mechanism disposed in the receiving portion for securing the input device to the receiving portion in a first direction substantially perpendicular to the bottom portion.

2. The electronic device as claimed in claim 1, wherein the receiving portion is partially surrounded with at least one side portion protruding from the bottom portion, and wherein the locking mechanism comprises at least one clasping member secured to the at least one side portion, each clasping member comprises a hook, the hook being deformed from a locked position extending out of the at least one side portion to an unlocked position being received hidden in the at least one side portion.

3. The electronic device as claimed in claim 2, wherein the hook is also capable of being driven to rotate from a first position to a second position, the hook is received in the at least one side portion in the first position and extends out of the at least one side portion in the second position.

4. The electronic device as claimed in claim 3, wherein the electronic device further comprises a fixing member for rotatably securing the at least one clasping member and a repositioning member secured to the fixing member, the repositioning member is used for driving the hook to rotate to the second position from the first position.

5. The electronic device as claimed in claim 4, wherein the locking mechanism further comprises a driving portion corresponding to the repositioning member and a connecting portion disposed between the driving portion and the hook, the connecting member is rotatably connected to the hook to drive the driving portion to change from an attached position to a detached position, and the driving portion is driven to return to the attached position under the drive of the repositioning member to drive the hook to rotate from the first position to the second position.

6. The electronic device as claimed in claim 1, wherein the electronic device further comprises a restricting mechanism for limiting the movement of the input device along a second direction perpendicular to the first direction.

7. The electronic device as claimed in claim 6, wherein the restricting mechanism is capable of interchanging between a first state to be at least partially inserted into the input device and a second state to be withdrawn from the input device.

8. The electronic device as claimed in claim 7, wherein the main body comprises a top case and one side wall protruding from the top case, the top case recesses to define the receiving portion, an opening at the side wall communicates with the receiving portion, and the input device is allowed to be removed out of the receiving portion through the opening along the second direction.

9. The electronic device as claimed in claim 7, wherein the electronic device further comprises a push mechanism being capable of sliding relative to the main body to drive the restricting mechanism to change from the first state to the second state.

10. The electronic device as claimed in claim 9, wherein the restricting mechanism comprises a body portion capable of interchanging between arch shaped and flat shaped, and the push mechanism comprises a resisting member abutting the body portion for driving the body portion to be flat shaped from arch shaped.

11. The electronic device as claimed in claim 10, wherein the push mechanism further comprises a spring for driving the resisting member to returns to original position after the input device is removed from the receiving portion.

12. The electronic device as claimed in claim 7, wherein the electronic device further comprises a repulsion mechanism for driving the input device to move along the second direction when the restricting mechanism is in the second state.

13. The electronic device as claimed in claim 12, wherein the repulsion mechanism comprises a first magnet disposed in the main body and a second magnet disposed in the input device with the magnetism thereof opposite to the first magnet.

14. An electronic device, comprising:
a main body defining a receiving portion, the receiving portion comprises a bottom portion;
an input device being capable of being secured to the receiving portion to function as a touchpad and being detached from the receiving portion to function as a wireless mouse, the input device comprising a first side end defining at least one first slot and a second side end defining at least one second slot;
a locking mechanism being capable of being inserted into the at least one first slot to limit the movement of the input device in a first direction substantially perpendicular to the bottom portion; and
a restricting mechanism being capable of being inserted into the at least one second slot to limit the movement of the input device in a second direction substantially perpendicular to the first direction and substantially parallel to the first direction.

15. The electronic device as claimed in claim 14, wherein the restricting mechanism comprises a body portion being capable of interchanging between arch shaped and flat shaped, the body portion is inserted into the input device when being arch shaped and is withdrawn from the input device when being flat shaped.

16. The electronic device as claimed in claim 15, wherein the electronic device further comprises a repulsion mechanism for driving the input device to move along the second direction when the body portion in flat shaped.

17. The electronic device as claimed in claim 16, wherein the electronic device further comprises a push mechanism slidable relative to the main body to drive the body portion to change from arch shaped to flat shaped.

18. The electronic device as claimed in claim 14, wherein the locking mechanism comprises a hook capable of being inserted into the input device to limit the movement of the input device along the first direction and capable of rotating around an axis extending substantially parallel to the first direction to change to a first position from a second position as the input device moves along the second direction, the hook is received in the main body in the first position and is exposed in the receiving portion in the second position.

19. The electronic device as claimed in claim 18, wherein the electronic device further comprises at least one repositioning member disposed in the at least one first slot for driving the hook to rotate around the axis to change from the first position to the second position.

20. The electronic device as claimed in claim 19, wherein the repositioning member is made of magnetic material.
